(19) United States
(12) Patent Application Publication
(10) Pub. No.: US 2025/0078938 A1
(43) Pub. Date: Mar. 6, 2025

(54) VOLTAGE GENERATION CIRCUIT AND SEMICONDUCTOR MEMORY DEVICE

(71) Applicant: Kioxia Corporation, Tokyo (JP)

(72) Inventor: Hiroshi YOSHIHARA, Fujisawa Kanagawa (JP)

(21) Appl. No.: 18/823,541

(22) Filed: Sep. 3, 2024

(30) Foreign Application Priority Data
Sep. 4, 2023 (JP) 2023-143048

(51) Int. Cl. G11C 16/28; G11C 16/30

(52) U.S. Cl. CPC G11C 16/28; G11C 16/30; G11C 2207/2254

(57) ABSTRACT

A voltage generation circuit is capable of curbing a peak current that occurs in a booster circuit. The voltage generation circuit includes a first circuit, a second circuit, and a first transistor having a gate to which a reference voltage is applied, a first terminal to which a power voltage is applied, and a second terminal connected to a first node. The first circuit is connected to the first node, boosts a first voltage at the first node, and outputs the boosted first voltage as a second voltage. The second circuit is connected to the first node and senses a first current flowing from the first transistor to the first circuit. The first circuit stops the boosting of the first voltage based on a sensing result from the second circuit.

### CROSS-REFERENCE TO RELATED APPLICATION(S)

This application is based upon and claims the benefit of priority from Japanese Patent Application No. 2023-143048, filed Sep. 4, 2023, the entire contents of which are incorporated herein by reference.

### FIELD

Embodiments described herein relate generally to a voltage generation circuit and a semiconductor memory device.

### BACKGROUND

Semiconductor memory devices having memory cells that store data in a nonvolatile manner include NAND flash memories. In a semiconductor memory device, a voltage generation circuit supplies voltages to various wires connected to memory cells.

### BRIEF DESCRIPTION OF THE DRAWINGS

FIG. 1 is a block diagram illustrating an example of a configuration of a memory system that includes a semiconductor memory device according to a first embodiment.

FIG. 2 is a circuit diagram illustrating an example of a configuration of a memory cell array in the semiconductor memory device according to the first embodiment.

FIG. 3 is a sectional view illustrating an example of a sectional structure of the memory cell array in the semiconductor memory device according to the first embodiment.

FIG. 4 is a sectional view illustrating an example of a sectional structure of a memory pillar in the semiconductor memory device according to the first embodiment.

FIG. 5 is a circuit diagram illustrating an example of a configuration of a voltage generation circuit in the semiconductor memory device according to the first embodiment.

FIG. 6 is a circuit diagram illustrating an example of a configuration of a booster circuit included in the voltage generation circuit in the semiconductor memory device according to the first embodiment.

FIG. 7 is a circuit diagram illustrating an example of a configuration of a charge pump included in the voltage generation circuit in the semiconductor memory device according to the first embodiment.

FIG. 8 is a graph illustrating an example of a waveform of a current flowing through the booster circuit in the voltage generation circuit according to the first embodiment and an example of a waveform of a current flowing through a booster circuit in a voltage generation circuit according to a comparative example.

FIG. 9 is a circuit diagram illustrating an example of a configuration of a voltage generation circuit in a semiconductor memory device according to a first modification of the first embodiment.

FIG. 10 is a circuit diagram illustrating an example of a configuration of a voltage generation circuit in a semiconductor memory device according to a second modification of the first embodiment.

FIG. 11 is a graph illustrating a relationship among voltages that are generated in the semiconductor memory device according to the first embodiment.

FIG. 12 is a circuit diagram illustrating an example of a configuration of a voltage generation circuit in a semiconductor memory device according to a second embodiment.

FIG. 13 is a flowchart illustrating an example of a calibration operation of the voltage generation circuit in the semiconductor memory device according to the second embodiment.

FIG. 14 is a flowchart illustrating an example of a setting operation of the voltage generation circuit in the semiconductor memory device according to the second embodiment.

### DETAILED DESCRIPTION

Embodiments provide a voltage generation circuit and a semiconductor memory device capable of curbing a peak current that occurs in a booster circuit.

In general, according to one embodiment, a voltage generation circuit includes a first circuit, a second circuit, and a first transistor having a gate to which a reference voltage is applied, a first terminal to which a power voltage is applied, and a second terminal connected to a first node. The first circuit is connected to the first node, boosts a first voltage at the first node, and outputs the boosted first voltage as a second voltage. The second circuit is connected to the first node and senses a first current flowing from the first transistor to the first circuit. The first circuit stops the boosting of the first voltage based on a sensing result from the second circuit.

Embodiments will be described below with reference to the drawings. Dimensions and ratios in the drawings are not necessarily the same as actual ones. In the following description, constituent elements having substantially the same function and configuration will be assigned the same reference numeral or symbol. When elements having similar configurations are distinguished from one another, different characters or numerals may be appended to the same reference numeral or symbol.

### 1. First Embodiment

### 1.1 Configuration

### 1.1.1 Configuration of Memory System

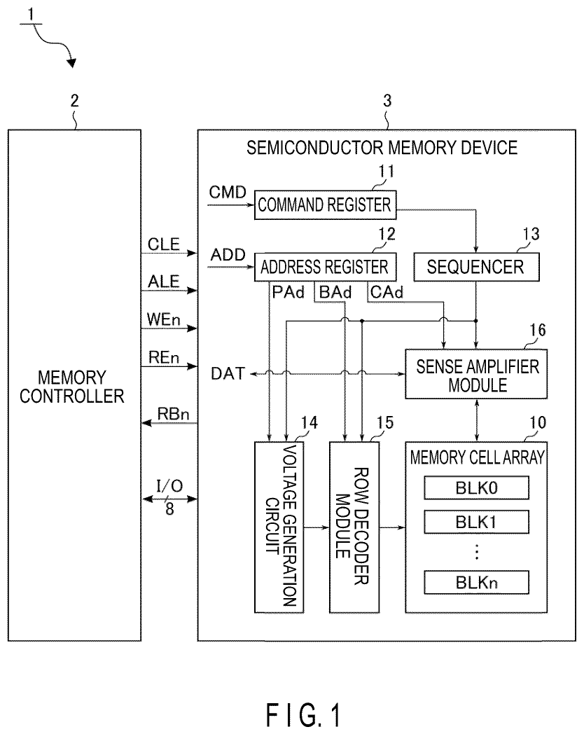

With reference to FIG. 1, a configuration of a memory system that includes a semiconductor memory device according to a first embodiment will be described. FIG. 1 is a block diagram illustrating an example of the configuration of the memory system. The memory system is a storage device configured to be connected to external host equipment (not illustrated). The memory system is, for example, a memory card such as an SD™ card, or a universal flash storage (UFS) or a solid state drive (SSD). A memory system 1 includes a memory controller 2 and a semiconductor memory device 3.

The memory controller 2 is a device that controls the semiconductor memory device 3. The memory controller 2 is, for example, a system-on-a-chip (SoC). The memory controller 2 controls the semiconductor memory device 3 based on a request from the host equipment. Specifically, for example, the memory controller 2 writes, to the semiconductor memory device 3, data as requested from the host equipment. The memory controller 2 also reads, from the semiconductor memory device 3, data as requested from the host equipment and transmits the read data to the host equipment.

The semiconductor memory device 3 is a memory that stores data in a nonvolatile manner. The semiconductor memory device 3 is, for example, a NAND flash memory.

### 1.1.2 Configuration of Semiconductor Memory Device

Continuing with reference to FIG. 1, a configuration of the semiconductor memory device 3 will be described.

The semiconductor memory device 3 includes, for example, a memory cell array 10, a command register 11, an address register 12, a sequencer 13, a voltage generation circuit 14, a row decoder module 15, and a sense amplifier module 16.

The memory cell array 10 includes a plurality of blocks BLK0 to BLKn (n is an integer equal to or greater than one). Hereinafter, when the blocks BLK0 to BLKn are not distinguished from one another, the blocks BLK0 to BLKn are each simply referred to as a block BLK. The block BLK is a set of memory cell transistors that can store data in a nonvolatile manner. The block BLK is, for example, used as a unit for erasing data. The memory cell array 10 is also provided with a plurality of bit lines and a plurality of word lines. Each of the memory cell transistors is, for example, connected to one of the bit lines and one of the word lines. The memory cell array 10 will be described later in detail.

The command register 11 is a circuit that stores commands CMD that the semiconductor memory device 3 receives from the memory controller 2. The commands CMD include, for example, a command that causes the sequencer 13 to execute a write operation, a read operation, and an erase operation.

The address register 12 is a circuit that stores an address ADD that the semiconductor memory device 3 receives from the memory controller 2. The address ADD includes, for example, a block address BAd, a page address PAd, and a column address CAd. The block address BAd, the page address PAd, and the column address CAd are used to select a block BLK, a word line, and a bit line.

The sequencer 13 is a circuit that controls an operation of other circuits according to a predetermined program. The sequencer 13 controls an operation of the entire semiconductor memory device 3. For example, the sequencer 13 controls the voltage generation circuit 14, the row decoder module 15, the sense amplifier module 16, and the like based on commands CMD stored in the command register 11. For example, the sequencer 13 executes a write operation, a read operation, and an erase operation.

The voltage generation circuit 14 is a circuit that generates a voltage to be used in a write operation, a read operation, an erase operation, or the like based on an instruction from the sequencer 13. For example, the voltage generation circuit 14 applies the generated voltage to a signal line corresponding to a selected word line, based on a page address PAd stored in the address register 12.

The row decoder module 15 is a circuit that selects one of the blocks BLK in the memory cell array 10 based on a block address BAd stored in the address register 12. For example, the row decoder module 15 transfers the voltage applied to the signal line corresponding to the selected word line to the selected word line in the selected block BLK.

The sense amplifier module 16 selects a bit line based on a column address CAd stored in the address register 12. In a write operation, the sense amplifier module 16 applies, to the selected bit line, a voltage based on data DAT to be written that is received from the memory controller 2. In a read operation, the sense amplifier module 16 determines data stored in a memory cell transistor based on a voltage of the selected bit line. The sense amplifier module 16 transfers a result of the determination as read data DAT to the memory controller 2.

The semiconductor memory device 3 having the configuration described above is connected to the memory controller 2 via a NAND interface not illustrated. Signals transmitted and received between the semiconductor memory device 3 and the memory controller 2 include, for example, a command latch enable signal CLE, an address latch enable signal ALE, a write enable signal WEn, a read enable signal REn, a ready/busy signal RBn, and an input/output signal I/O. Using these signals, the memory controller 2 controls the semiconductor memory device 3.

The signal CLE is a signal indicating that a signal I/O received by the semiconductor memory device 3 is a command CMD. The signal ALE is a signal indicating that a signal I/O received by the semiconductor memory device 3 is an address ADD. The signal WEn is a signal that commands the semiconductor memory device 3 to accept inputs through the signal I/O. The signal REn is a signal that commands the semiconductor memory device 3 to output through the signal I/O. The signals CLE, ALE, WEn, and REn are transmitted from the memory controller 2 to the semiconductor memory device 3.

The signal RBn is a signal indicating that the semiconductor memory device 3 is in either a ready state or a busy state. For example, when the semiconductor memory device 3 is in the busy state, the signal RBn is brought to an “L” level. The ready state is a state in which the semiconductor memory device 3 is ready to receive a command CMD from the memory controller 2. The busy state is a state in which the semiconductor memory device 3 is not ready to receive a command CMD from the memory controller 2. The signal RBn is transmitted from the semiconductor memory device 3 to the memory controller 2.

The signal I/O is, for example, an 8-bit signal. The signal I/O contains data that is transmitted and received between the semiconductor memory device 3 and the memory controller 2. The signal I/O includes, for example, a command CMD, an address ADD, and data DAT.

### 1.1.3 Circuit Configuration of Memory Cell Array

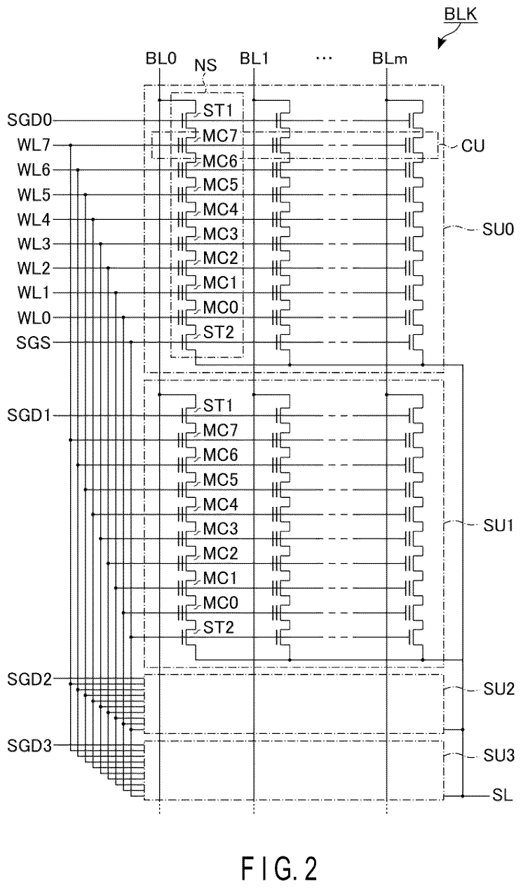

With reference to FIG. 2, a circuit configuration of the memory cell array 10 will be described. FIG. 2 is a circuit diagram illustrating an example of a configuration of the memory cell array 10. FIG. 2 illustrates a circuit configuration of a block BLK included in the memory cell array 10 as an example of the circuit configuration of the memory cell array 10. The other blocks BLK also have a configuration similar to that in FIG. 2.

The block BLK includes, for example. four string units SU0 to SU3. Hereinafter, when the string units SU0 to SU3 are not distinguished from one another, the string units SU0 to SU3 are each simply referred to as a string unit SU. The string unit SU is, for example, a group of NAND strings NS that are collectively selected in a write operation or a read operation. The string unit SU includes the plurality of NAND strings NS that are connected to respective bit lines BL0 to BLm (m is an integer equal to or greater than one). Hereinafter, when the bit lines BL0 to BLm are not distinguished from one another, the bit lines BL0 to BLm are each simply referred to as a bit line BL. Each NAND string NS is a group of transistors that are connected together in series. The plurality of transistors connected together in series include, for example, memory cell transistors MC0 to MC7 and selection transistors ST1 and ST2. Hereinafter, when the memory cell transistors MC0 to MC7 are not distinguished from one another, the memory cell transistors MC0 to MC7 are each simply referred to as a memory cell transistor MC. The memory cell transistor MC stores data in a nonvolatile manner. The memory cell transistor MC includes a control gate and a charge accumulation layer. The selection transistors ST1 and ST2 are switching elements. The selection transistors ST1 and ST2 are each used for selecting a string unit SU in various operations.

In the NAND strings NS, the memory cell transistors MC0 to MC7 are connected together in series. A drain of the selection transistor ST1 is connected to a connected bit line BL. A source of the selection transistor ST1 is connected to one end of the memory cell transistors MC0 to MC7. A drain of the selection transistor ST2 is connected to the other end of the memory cell transistors MC0 to MC7. A source of the selection transistor ST2 is connected to a source line SL.

In the same block BLK, control gates of respective memory cell transistors MC0 to MC7 across all NAND strings NS are connected to respective word lines WL0 to WL7 in common. Hereinafter, when the word lines WL0 to WL7 are not distinguished from one another, the word lines WL0 to WL7 are each simply referred to as a word line WL. In the string units SU0 to SU3, gates of the respective selection transistors ST1 are connected to respective selection gate lines SGD0 to SGD3 in common. Hereinafter, when the selection gate lines SGD0 to SGD3 are not distinguished from one another, the selection gate lines SGD0 to SGD3 are each simply referred to as a selection gate line SGD. Gates of selection transistors ST2 included in the same block BLK are connected to a selection gate line SGS in common.

In the circuit configuration of the memory cell array 10 described above, for example, a bit line BL is shared by a plurality of NAND strings NS across the plurality of string units SU to which the same column address CAd is allocated. The source line SL is shared across, for example, the plurality of blocks BLK.

In a string unit SU, a group of memory cell transistors MC connected to a common word line WL is referred to as, for example, a cell unit CU. Each block BLK includes a plurality of cell units CU. Data stored in a cell unit CU including a plurality of memory cell transistors MC each storing a 1-bit data item based on a threshold voltage is equivalent to a 1-page data item. Each cell unit CU can store data that is equal to or larger than a 2-page data item based on the number of bits of data stored in its memory cell transistors MC.

The circuit configuration of the memory cell array 10 is not limited to the configuration described above. For example, the number of the string units SU included in the block BLK, the number of the memory cell transistors MC and the selection transistors ST1 and ST2 included in the NAND string NS may each be a different number. Hereinafter, the memory cell transistors MC will be also referred to as memory cells MC.

### 1.1.4 Structure of Memory Cell Array

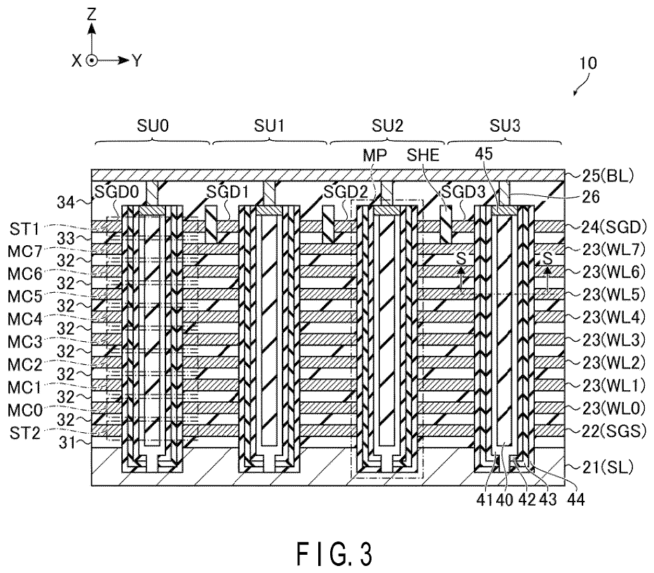

With reference to FIG. 3, a sectional structure of the memory cell array 10 will be described. FIG. 3 is a sectional view illustrating an example of the sectional structure of the memory cell array 10. FIG. 3 illustrates a region corresponding to a block BLK. In FIG. 3, an X direction corresponds to a direction in which word lines WL extend. A Y direction corresponds to a direction in which a bit line BL extends. A Z direction corresponds to a direction perpendicular to a surface of a semiconductor substrate (not illustrated) of the semiconductor memory device 3.

The memory cell array 10 includes conductive layers 21 to 26, insulating layers 31 to 34, a plurality of memory pillars MP, and a plurality of members SHE.

The conductive layer 21 is formed in, for example, a plate shape that extends along an XY plane. The conductive layer 21 is used as the source line SL. The conductive layer 21 is formed of a conductive material, which is, for example, an N-type semiconductor to which an impurity is added or a metallic material. Note that the conductive layer 21 may be of, for example, a stacked structure of a semiconductor and a metal.

On an upper surface of the conductive layer 21, the insulating layer 31 is provided. On an upper surface of the insulating layer 31, the conductive layer 22 is provided. The conductive layer 22 is formed in, for example, a plate shape that extends along an XY plane. The conductive layer 22 is used as the selection gate line SGS. The conductive layer 22 contains, for example, tungsten.

On an upper surface of the conductive layer 22, eight insulating layers 32 and eight conductive layers 23 are alternately stacked. The conductive layer 23 is formed in, for example, a plate shape that extends along an XY plane. The stacked conductive layers 23 are used as the word lines WL0 to WL7, which are stacked in this order from the selection gate line SGS. The conductive layer 23 contains, for example, tungsten.

On an upper surface of an uppermost conductive layer 23, the insulating layer 33 is provided. On an upper surface of the insulating layer 33, the conductive layer 24 is provided. The conductive layer 24 is formed in, for example, a plate shape that extends along an XY plane. The conductive layer 24 is used as the selection gate line SGD. The conductive layer 24 contains, for example, tungsten.

On an upper surface of the conductive layer 24, the insulating layer 34 is provided. On an upper surface of the insulating layer 34, the conductive layer 25 is provided. The conductive layer 25 is formed in, for example, a line shape that extends in the Y direction. The conductive layer 25 is used as the bit line BL. The conductive layer 25 contains, for example, copper.

The memory pillars MP are provided extending in the Z direction. The memory pillars MP penetrate the insulating layers 31 and 33, the insulating layers 32, the conductive layers 22 and 24, and the conductive layers 23.

The memory pillars MP each include, for example, a core member 40, a semiconductor film 41, insulating films 42 to 44, and a semiconductor part 45.

The core member 40 is formed at a center portion of each memory pillar MP in a columnar shape that extends along the Z direction. An upper end of the core member 40 is included in, for example, a layer above the conductive layer 24. A lower end of the core member 40 is included in, for example, a layer below the conductive layer 22. The core member 40 contains, for example, silicon oxide.

Side surfaces and a lower surface of the core member 40 are covered with the semiconductor film 41. The semiconductor film 41 functions as a channel of each of the memory cell transistors MC and the selection transistors ST1 and ST2. A lower end of the semiconductor film 41 is in contact with the conductive layer 21. The semiconductor film 41 contains, for example, polysilicon.

Side surfaces of the semiconductor film 41 are covered with a stacked body of the insulating films 42 to 44.

In a portion above the core member 40 and the semiconductor film 41, the semiconductor part 45 is formed. The semiconductor part 45 is electrically connected to the semiconductor film 41. Side surfaces of the semiconductor part 45 are covered with, for example, the stacked body of the insulating films 42 to 44. The semiconductor part 45 can be formed integrally with the semiconductor film 41. An upper surface of the semiconductor part 45 is in contact with the conductive layer 26. The conductive layer 26 is connected to the conductive layer 25, thus electrically connecting the memory pillar MP and the conductive layer 25. The conductive layer 26 contains, for example, copper.

In the configuration of the memory pillar MP described above, for example, a portion in which the memory pillar MP and the conductive layer 22 intersect functions as the selection transistor ST2. Portions in which the memory pillar MP and the eight conductive layers 23 intersect function as the memory cell transistors MC0 to MC7. A portion in which the memory pillar MP and the conductive layer 24 intersect functions as the selection transistor ST1.

The members SHE extend in the Z direction, dividing the conductive layer 24 in the Y direction. The members SHE contain, for example, an insulator. Conductive layers 24 divided by the members SHE correspond to the selection gate lines SGD0 to SGD3.

Configurations as described above are arranged in a depth direction of the paper of FIG. 3 (the X direction), and a set of NAND strings NS arranged in the X direction constitute a string unit SU.

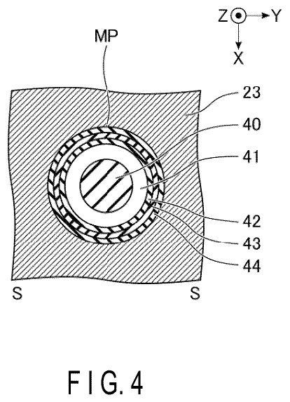

FIG. 4 is a sectional view taken along the S-S line in FIG. 3, illustrating an example of a sectional structure of the memory pillar MP. Specifically, FIG. 4 illustrates a sectional structure of the memory pillar MP in a layer that is parallel to a surface of the semiconductor substrate and includes the conductive layer 23.

As illustrated in FIG. 4, the insulating film 42 wraps around the semiconductor film 41. The insulating film 42 functions as tunnel insulating films of the memory cell transistors MC. The insulating film 42 contains, for example, silicon oxide or silicon oxynitride. The insulating film 43 wraps around the insulating film 42. The insulating film 43 functions as charge accumulation layers of the memory cell transistors MC. The insulating film 43 contains, for example, silicon nitride. The insulating film 44 wraps around the insulating film 43. The insulating film 44 functions as block insulating films of the memory cell transistors MC. The insulating film 44 contains, for example, silicon oxide or aluminum oxide. The conductive layer 23 wraps around the insulating film 44.

### 1.1.5 Configuration of Voltage Generation Circuit

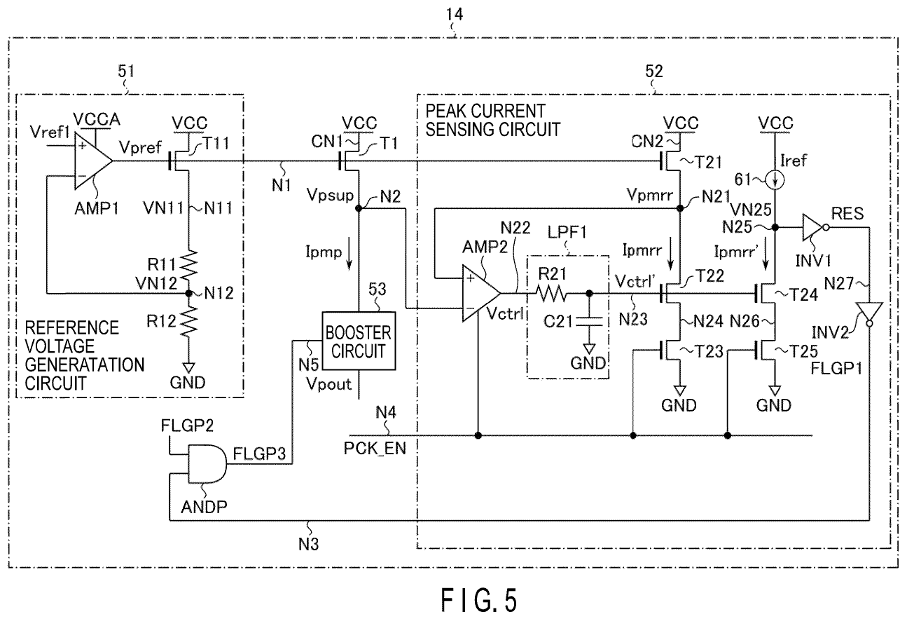

With reference to FIG. 5, a configuration of the voltage generation circuit 14 will be described. FIG. 5 is a circuit diagram illustrating an example of the configuration of the voltage generation circuit 14. Note that, in the following description, any one of the source and the drain of the transistor may be referred to as a “first terminal of the transistor”, and the other of the source and the drain of the transistor will be referred to as a “second terminal of the transistor.”

The voltage generation circuit 14 includes, for example, a reference voltage generation circuit 51, an n-channel MOS transistor T1, a peak current sensing circuit 52, a logical product circuit (AND circuit) ANDP, and a booster circuit 53.

The reference voltage generation circuit 51 is a circuit that generates a reference voltage Vpref to be applied to a gate of the transistor T1. The voltage Vpref is a reference voltage for generating a voltage to be supplied to the booster circuit 53 with a source follower. The reference voltage generation circuit 51 is connected to a node N1. The reference voltage generation circuit 51 supplies the generated reference voltage Vpref via the node N1 to the gate of the transistor T1 and the peak current sensing circuit 52. The reference voltage generation circuit 51 will be described later in detail.

The transistor T1 is a transistor that drives the booster circuit 53. The transistor T1 is, for example, an n-channel MOS transistor having a gate width W. The gate of the transistor T1 is connected to the node N1. That is, the voltage Vpref is applied to the gate of the transistor T1. To a first terminal of the transistor T1, a power voltage VCC is applied. A second terminal of the transistor T1 is connected to a node N2. To the booster circuit 53, a voltage that is clamped at the voltage Vpref by the transistor T1 is supplied. A voltage drop affected by a threshold voltage Vth1 of the transistor T1 causes the voltage supplied to the booster circuit 53 to be a voltage lower than the voltage VCC. Hereinafter, the voltage supplied to the booster circuit 53, that is, a voltage at the node N2 will be referred to as a “voltage Vpsup.” A current that flows to the booster circuit 53 as the voltage Vpsup is supplied will be referred to as a “current Ipmp.”

Note that the voltage generation circuit 14 includes a wire CN1 for supplying the voltage VCC to the transistor T1. To one end of the wire CN1, the voltage VCC is supplied. The other end of the wire CN1 is connected to the first terminal of the transistor T1.

The voltage applied to the gate of the transistor T1 is controlled to be the voltage Vpref by the reference voltage generation circuit 51, so that the voltage Vpsup at the node N2 is controlled to be a substantially constant voltage. This can prevent a voltage boosted by the booster circuit 53 from becoming excessively high to break the booster circuit 53 itself or another circuit and the like.

The peak current sensing circuit 52 is a circuit that senses a peak of the current Ipmp flowing from the transistor T1 to the booster circuit 53 (hereinafter, will be also referred to as a “peak current”). The peak current is an overcurrent that flows instantaneously (a current that takes a peak value in terms of average value per unit time (e.g., 1 μs)). The peak current sensing circuit 52 is connected to nodes N1 to N4. The peak current sensing circuit 52 senses the peak of the current Ipmp based on the voltage Vpref supplied from the reference voltage generation circuit 51 via the node N1 and the voltage Vpsup at the node N2. As a sensing result of the peak current, the peak current sensing circuit 52 transmits a signal FLGP1 to the logical product circuit ANDP via the node N3. The signal FLGP1 is a signal indicating, based on the sensing result of the peak current, whether the booster circuit 53 is to perform voltage boosting. The signal FLGP1 is generated by the peak current sensing circuit 52. Note that, in the present specification, not only a result as to whether the peak current is sensed but also the signal FLGP1 transmitted from the peak current sensing circuit 52 is also referred to as the “sensing result.”

To the peak current sensing circuit 52, a signal PCK_EN is also input from the node N4. The signal PCK_EN is a signal for controlling the sensing of the peak current. For example, the signal PCK_EN is generated by the sequencer 13. The sequencer 13 transmits the generated signal PCK_EN to the voltage generation circuit 14 (in particular, to the peak current sensing circuit 52).

For example, when the sensing of the peak current is to be executed, the sequencer 13 generates the signal PCK_EN at an “H” level. Based on the signal PCK_EN at the “H” level, the peak current sensing circuit 52 executes the sensing of the peak current (hereinafter, will be also referred to as a “peak current sensing operation”). When the peak of the current Ipmp is sensed, the peak current sensing circuit 52 transmits the signal FLGP1 at the “L” level to the logical product circuit ANDP. In this case, the signal FLGP1 at the “L” level means that the booster circuit 53 is to stop the voltage boosting. When the peak of the current Ipmp is not sensed, the peak current sensing circuit 52 transmits the signal FLGP1 at the “H” level to the logical product circuit ANDP. In this case, the signal FLGP1 at the “H” level means that the booster circuit 53 is to execute the voltage boosting. On the other hand, when the sensing of the peak current is not to be executed, the sequencer 13 generates the signal PCK_EN at the “L” level. Based on the signal PCK_EN at the “L” level, the peak current sensing circuit 52 does not execute the sensing of the peak current. The peak current sensing circuit 52 will be described later in detail.

The logical product circuit ANDP includes a first terminal, a second terminal, and a third terminal.

To the first terminal of the logical product circuit ANDP, the sensing result (the signal FLGP1) is input from the peak current sensing circuit 52 via the node N3.

To the second terminal of the logical product circuit ANDP, a signal FLGP2 is input. The signal FLGP2 is a signal indicating, based on a voltage Vpout that is output from the booster circuit 53, whether the booster circuit 53 is to perform the voltage boosting. The signal FLGP2 is generated based on the voltage Vpout by, for example, a voltage level sensing circuit not illustrated. The voltage level sensing circuit transmits the generated signal FLGP2 to the voltage generation circuit 14 (the logical product circuit ANDP).

For example, the voltage level sensing circuit includes a voltage ladder and a comparator. The voltage ladder includes a variable resistor, a resistance value of which can be adjusted with a binary signal supplied from the sequencer 13. This enables the voltage level sensing circuit to adjust a sensing level based on the binary signal. The voltage Vpout is divided by the voltage ladder. The comparator includes a noninverting input terminal, an inverting input terminal, and an output terminal. To the noninverting input terminal of the comparator, a target voltage is applied. The target voltage is, for example, a voltage VREAD that is applied to non-selected word lines WL in a read operation, a voltage VPASS that is applied to non-selected word lines WL in a write operation, a voltage VPGM that is applied to a selected word line WL in a write operation, or the like. To the inverting input terminal of the comparator, a voltage divided by the voltage ladder (hereinafter, will be referred to as a “voltage Vpout”) is applied. The comparator compares the voltage Vpout′ with the target voltage and outputs a result of the comparison as the signal FLGP2 from the output terminal. When the voltage Vpout′ is equal to or lower than the target voltage, the comparator outputs the signal FLGP2 at the “H” level. On the other hand, when the voltage Vpout′ is higher than the target voltage, the comparator outputs the signal FLGP2 at the “L” level. The output terminal of the comparator is connected to the second terminal of the logical product circuit ANDP. Note that, between the output terminal of the comparator and the second terminal of the logical product circuit ANDP, two inverters may be connected in series.

When the voltage Vpout′ is higher than the target voltage, the voltage level sensing circuit determines that the voltage boosting is to be stopped and generates the signal FLGP2 at the “L” level. In this case, the signal FLGP2 at the “L” level means that the booster circuit 53 is to stop the voltage boosting. On the other hand, when the voltage Vpout′ is equal to or lower than the target voltage, the voltage level sensing circuit determines that the voltage boosting is not to be stopped and generates the signal FLGP2 at the “H” level. In this case, the signal FLGP2 at the “H” level means that the booster circuit 53 is to execute the voltage boosting.

A value of the target voltage described above is controlled with the binary signal supplied from the sequencer 13. As the value of the target voltage, the value needed in a memory cell MC, such as the voltage VREAD, the voltage VPASS, or the voltage VPGM, is basically output from the sequencer 13 at a necessary timing. However, in some cases, a voltage may be stepped up at a certain rate to the value of the target voltage such that the stepping up the voltage to the target voltage is completed before the necessary timing (i.e., ramp rate control). Such control will be referred to as “first control.” The ramp rate is controlled in this manner so as to control a bias applied to the memory cell MC within a certain range irrespective of variations, individual differences, and a circuit system/configuration of charge pumps described later or to curb the peak current by restraining operation of the charge pumps.

A degree of the current Ipmp that the charge pumps generate at a certain ramp rate depends on an output load capacitance of each charge pump. Controlling the ramp rate is effective in curbing the peak current. However, it is not possible to guarantee an absolute value of an upper limit of the peak current because, with an output load capacitance formed by the memory cells MC, the peak current intricately fluctuates (increases and decreases) with voltage states of insides of the memory cells MC such as memory holes.

The logical product circuit ANDP calculates a logical product of the signal FLGP1 and the signal FLGP2 to generate a signal FLGP3 as a result of the calculation. The signal FLGP3 is a signal indicating whether the booster circuit 53 is to perform the voltage boosting or not. More specifically, when the signals FLGP1 and FLGP2 are both at the “H” level, the logical product circuit ANDP generates the signal FLGP3 at the “H” level. In this case, the signal FLGP3 at the “H” level means that the booster circuit 53 is to execute the voltage boosting. On the other hand, when at least one of the signals FLGP1 and FLGP2 is at the “L” level, the logical product circuit ANDP generates the signal FLGP3 at the “L” level. In this case, the signal FLGP3 at the “L” level means that the booster circuit 53 is to stop the voltage boosting. From the third terminal of the logical product circuit ANDP, the result of the calculation (the signal FLGP3) is output to the booster circuit 53 via a node N5.

The booster circuit 53 is a circuit that boosts the voltage Vpsup at the node N2 and outputs the voltage Vpout that is the boosted voltage of Vpsup. The booster circuit 53 is connected to the nodes N2 and N5. To the booster circuit 53, the signal FLGP3 is input via the node N5 from the logical product circuit ANDP. Based on the signal FLGP3, the booster circuit 53 executes or stops the voltage boosting.

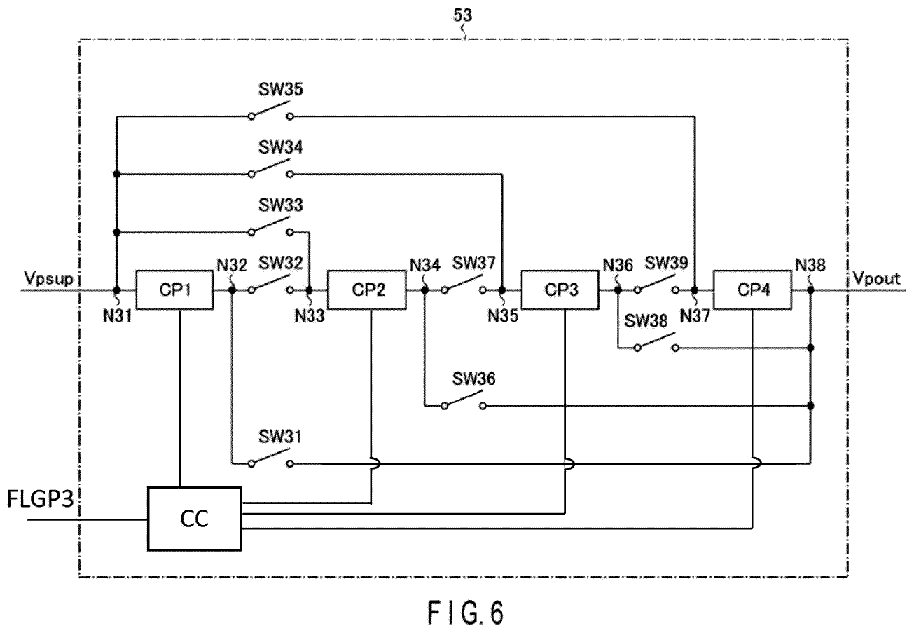

For example, when the signal FLGP3 is at the “H” level, the booster circuit 53 executes the voltage boosting. More specifically, a control circuit CC (which will be described later referring to FIG. 6) activates the respective charge pumps CP1 to CP4. The voltage Vpout being the boosted voltage of Vpsup is, for example, a voltage that is applied to various wires such as word lines WL and the source line SL in an operation such as a write operation, a read operation, or an erase operation. The voltage Vpout being the boosted voltage of Vpsup is output from the booster circuit 53 and further output from the voltage generation circuit 14, and then supplied via the row decoder module 15 to the memory cells MC. That is, the semiconductor memory device 3 is configured to supply the voltage Vpout to the memory cells MC. On the other hand, when the signal FLGP3 is at the “L” level, the booster circuit 53 stops (does not execute) the voltage boosting. More specifically, the control circuit CC deactivates the respective charge pumps CP1 to CP4 based on the signal FLGP3.

Note that the signal FLGP3 is a result of the calculation of the logical product of the signal FLGP1 and the signal FLGP2. That is, the signal FLGP3 is a signal based on the signals FLGP1 and FLGP2. Accordingly, the booster circuit 53 stops the voltage boosting based on the sensing result from the peak current sensing circuit 52 (the signal FLGP1). Specifically, when the peak current sensing circuit 52 senses a peak of the current Ipmp, the booster circuit 53 stops the voltage boosting. At this time, the sensing result indicates that the peak current sensing circuit 52 has sensed the peak of the current Ipmp. In addition, the booster circuit 53 stops the voltage boosting based further on the signal FLGP2. The booster circuit 53 will be described later in detail.

1.1.6 Configuration of Reference Voltage Generation Circuit

The reference voltage generation circuit 51 includes, for example, an n-channel MOS transistor T11, resistive elements R11 and R12, and an operational amplifier AMP1.

A gate of the transistor T11 is connected to the node N1. To a first terminal of the transistor T11, the power voltage VCC is applied. A second terminal of the transistor T11 is connected to a node N11.

One end of the resistive element R11 is connected to the node N11. The other end of the resistive element R11 is connected to a node N12. One end of the resistive element R12 is connected to the node N12. The other end of the resistive element R12 is grounded. That is, a voltage VN12 at the node N12 is a voltage that is a voltage VN11 at the node N11 divided based on a resistance value ratio between the resistive elements R11 and R12.

The operational amplifier AMP1 includes a first input terminal, a second input terminal, and an output terminal. The first input terminal of the operational amplifier AMP1 is a noninverting input terminal. The second input terminal of the operational amplifier AMP1 is an inverting input terminal. To the first input terminal of the operational amplifier AMP1, a reference voltage Vref1 is applied. The second input terminal of the operational amplifier AMP1 is connected to the node N12. The output terminal of the operational amplifier AMP1 is connected to the node N1. The operational amplifier AMP1 is supplied with a voltage VCCA. Based on a result of comparing the voltage Vref1 applied to the first input terminal and the voltage VN12 at the node N12 applied to the second input terminal, the operational amplifier AMP1 generates the voltage Vpref. The operational amplifier AMP1 generates such a voltage Vpref as to make the voltages Vref1 and VN12 equal to each other. The operational amplifier AMP1 supplies the generated voltage Vpref via the node N1 to the gate of the transistor T11, the gate of the transistor T1, and the peak current sensing circuit 52.

The reference voltage generation circuit 51 includes the source follower for the transistor T11, thus being a circuit that generates the voltage Vpref, which is higher than the voltage VN11 at the node N11 by a threshold voltage Vth11 of the transistor T1l. With a configuration that makes a ratio between the gate width W of the transistor T1 and a gate width W11 of the transistor T11 match a ratio between an expectation value of a current consumption Ipmp of the booster circuit 53 and a current I11 flowing through the transistor T11, it is possible to bring the voltage Vpsup supplied to the booster circuit 53 to the same voltage level as the voltage VN11.

### 1.1.7 Configuration of Peak Current Sensing Circuit

The peak current sensing circuit 52 includes, for example, n-channel MOS transistors T21 to T25, an operational amplifier AMP2, a low-pass filter LPF1, a current source 61, and inverters INV1 and INV2.

The transistor T21 is, for example, an n-channel MOS transistor having a gate width w (w<W). That is, the transistor T21 is smaller in size than the transistor T1. A gate of the transistor T21 is connected to the node N1. That is, the voltage Vpref is applied to the gate of the transistor T21. To a first terminal of the transistor T21, the power voltage VCC is applied. A second terminal of the transistor T21 is connected to a node N21. To the node N21, a voltage that is clamped at the voltage Vpref by the transistor T21 is supplied. A voltage drop affected by a threshold voltage Vth21 of the transistor T21 causes the voltage supplied to the node N21, that is, a voltage at the node N21, to be a voltage lower than the voltage VCC.

To the first terminals of the transistor T1 and the transistor T21, the voltage VCC is applied. The second terminal of the transistor T1 serves as one of inputs of the operational amplifier AMP2, the second terminal of the transistor T21 serves as the other of the inputs of the operational amplifier AMP2 to which feedback is applied, and the second terminal of the transistor T1 and the second terminal of the transistor T21 are in a virtual ground condition. For this reason, the second terminal of the transistor T1 and the second terminal of the transistor T21 are at the same potential. To the gates of the transistor T1 and the transistor T21, the voltage Vpref is applied.

As seen from the above, the transistor T1 and the transistor T21 are in a current mirror relation, a ratio between currents flowing through the transistor T1 and the transistor T21 is a ratio between sizes of the transistor T1 and the transistor T21, specifically, W:w. For this reason, a current flowing from the transistor T21 to the node N21 is Ipmp×(w/W). For example, in a case of W=10000 (μm) and w=10 (μm), the current is Ipmp/1000. Since the current is lower than the current Ipmp, a power consumption of the peak current sensing circuit 52 can be reduced. Hereinafter, the voltage at the node N21 will be referred to as the “voltage Vpmrr.” A current that is caused to flow from the transistor T21 to the node N21 by supply of the voltage Vpmrr will be referred to as a “current Ipmrr.”

The peak current sensing circuit 52 includes a source follower for the transistor T21. The current Ipmrr is expected to be lower (e.g., several μA) than the current Ipmp, and thus the gate width w of the transistor T21 is designed such that w=W×(Ipmrr/Ipmp) is satisfied.

Note that the peak current sensing circuit 52 includes a wire CN2 for supplying the voltage VCC to the transistor T21. To one end of the wire CN2, the voltage VCC is supplied. The other end of the wire CN2 is connected to the first terminal of the transistor T21.

The operational amplifier AMP2 includes a first input terminal, a second input terminal, a control terminal, and an output terminal. The first input terminal of the operational amplifier AMP2 is an inverting input terminal. The second input terminal of the operational amplifier AMP2 is a noninverting input terminal. The first input terminal of the operational amplifier AMP2 is connected to the node N2. The second input terminal of the operational amplifier AMP2 is connected to the node N21. To the control terminal of the operational amplifier AMP2, the signal PCK_EN is input via the node N4. The output terminal of the operational amplifier AMP2 is connected to a node N22.

When the signal PCK_EN is at the “H” level, the operational amplifier AMP2 operates, in accordance with the signal PCK_EN at the “H” level. The operational amplifier AMP2 generates a voltage Vctrl based on a result of comparing the voltage Vpsup at the node N2 applied to the first input terminal and the voltage Vpmrr at the node N21 applied to the second input terminal. The operational amplifier AMP2 generates such a voltage Vctrl as to make the voltages Vpsup and Vpmrr equal to each other. The operational amplifier AMP2 supplies the generated voltage Vctrl from the output terminal via the node N22 to the low-pass filter LPF1.

On the other hand, when the signal PCK_EN is at the “L” level, the operational amplifier AMP2 does not operate, in accordance with the signal PCK_EN at the “L” level.

One end of the low-pass filter LPF1 is connected to the node N22. That is, the one end of the low-pass filter LPF1 is connected to the output terminal of the operational amplifier AMP2 via the node N22. The other end of the low-pass filter LPF1 is connected to a node N23. That is, the other end of the low-pass filter LPF1 is connected to a gate of the transistor T22 via the node N23. The low-pass filter LPF1 supplies a voltage Vctrl′, which is the voltage Vctrl supplied from the operational amplifier AMP2 with noise removed, to the gate of the transistor T22 via the node N23. The low-pass filter LPF1 includes a resistive element R21 and a capacitive element C21.

One end of the resistive element R21 is connected to the node N22. The other end of the resistive element R21 is connected to the node N23. A first electrode of the capacitive element C21 is connected to the node N23. A second electrode of the capacitive element C21 is grounded.

The gate of the transistor T22 is connected to the node N23. That is, to the gate of the transistor T22, the voltage Vctrl′ based on the voltage Vctrl is applied. A first terminal of the transistor T22 is connected to the node N21. A second terminal of the transistor T22 is connected to a node N24. When the transistor T22 is brought to an on-state, the current Ipmrr (=Ipmp×(w/W)) flows from the transistor T22 to the node N24. The voltage Vctrl output from the operational amplifier AMP2, more exactly, the voltage Vctrl′ controls the current Ipmrr flowing through the transistor T22.

To a gate of a transistor T23, the signal PCK_EN is input. A first terminal of the transistor T23 is connected to the node N24. The second terminal of the transistor T23 is grounded. When the signal PCK_EN is at the “H” level, the transistor T23 is brought to the on-state. On the other hand, when the signal PCK_EN is at the “L” level, the transistor T23 is brought to an off-state.

When the voltage Vpmrr at the node N21 is higher than the voltage Vpsup at the node N2, the voltage Vctrl output from the operational amplifier AMP2 drops. That also causes the voltage Vctrl′ to drop, and thus the current Ipmrr flowing from the transistor T22 to the node N24 is decreased. For this reason, the voltage Vpmrr at the node N21 drops. When the voltage Vpmrr at the node N21 is lower than the voltage Vpsup at the node N2, the voltage Vctrl output from the operational amplifier AMP2 rises. That also causes the voltage Vctrl′ to rise, and thus the current Ipmrr flowing from the transistor T22 to the node N24 is increased. For this reason, the voltage Vpmrr at the node N21 rises. In this manner, the operational amplifier AMP2 is subjected to feedback control such that the voltages Vpsup and Vpmrr are equal to each other. For this reason, the current Ipmrr is a current that reflects a value of the current Ipmp (a current corresponding to the current Ipmp).

The current source 61 is a circuit that supplies a reference current Iref. To one end of the current source 61, the power voltage VCC is applied. The other end of the current source 61 is connected to a node N25. The current source 61 supplies the current Iref to the node N25.

A transistor T24 is, for example, the same in size as the transistor T22. A gate of the transistor T24 is connected to the node N23. A first terminal of the transistor T24 is connected to the node N25. A second terminal of the transistor T24 is connected to a node N26. When the transistor T24 is brought to the on-state, a current flows from the transistor T24 to the node N26. Since the transistor T24 is the same in size as the transistor T22, and the voltage Vctrl′ is applied to the gate of the transistor T24, a current flowing from the transistor T24 to the node N26 is a current that is the same in magnitude as the current Ipmrr (mirror current). That is, the current flowing from the transistor T24 to the node N26 is a current that reflects a value of the current Ipmrr (a current corresponding to the current Ipmrr). Hereinafter, the current flowing from the transistor T24 to the node N26 will be referred to as a “current Ipmrr′.”

To a gate of a transistor T25, the signal PCK_EN is input. A first terminal of the transistor T25 is connected to the node N26. The second terminal of the transistor T25 is grounded. When the signal PCK_EN is at the “H” level, the transistor T25 is brought to the on-state. On the other hand, when the signal PCK_EN is at the “L” level, the transistor T25 is brought to the off-state.

An input terminal of the inverter INV1 is connected to the node N25. An output terminal of the inverter INV1 is connected to a node N27.

When the current Ipmrr′ is higher than the current Iref, a voltage VN25 at the node N25 drops (to the “L” level). When the current Ipmrr′ is lower than the current Iref, the voltage VN25 at the node N25 rises (to the “H” level). That is, the voltage VN25 at the node N25 stands at one of voltage levels (the “H” level/“L” level) that reflects a magnitude relation between the current Ipmrr′ and the current Iref. When the voltage VN25 at the node N25 applied to the input terminal of the inverter INV1 is at the “L” level, the inverter INV1 outputs a signal RES at the “H” level that is generated based on the voltage VN25. On the other hand, when the voltage VN25 at the node N25 applied to the input terminal of the inverter INV1 is at the “H” level, the inverter INV1 outputs the signal RES at the “L” level that is generated based on the voltage VN25. That is, the signal RES output from the inverter INV1 also stands at one of logic levels (the “H” level/“L” level) that reflects the magnitude relation between the current Ipmrr′ and the current Iref.

With the configuration described above, the peak current sensing circuit 52 can determine whether the current Ipmrr′ is higher than the current Iref or not. As described above, the current Ipmrr′ is the current that reflects the value of the current Ipmp. That is, when the current Ipmp reaches its peak, the current Ipmrr′ also reaches its peak. Accordingly, the peak current sensing circuit 52 can sense the peak of the current Ipmp based on the current Ipmrr′, more exactly, by comparing the current Ipmrr′ with the current Iref. When the current Ipmrr′ is higher than the current Iref, the peak current sensing circuit 52 determines that the peak of the current Ipmp is sensed. On the other hand, when the current Ipmrr′ is lower than the current Iref, the peak current sensing circuit 52 determines that the peak of the current Ipmp is not sensed.

An input terminal of the inverter INV2 is connected to the node N27. An output terminal of the inverter INV2 is connected to the node N3. When the signal RES input to the input terminal of the inverter INV2 is at the “H” level, that is, when the peak current sensing circuit 52 senses the peak of the current Ipmp, the inverter INV2 outputs the signal FLGP1 at the “L” level that is generated based on the signal RES. On the other hand, when the signal RES input to the input terminal of the inverter INV2 is at the “L” level, that is, when the peak current sensing circuit 52 does not sense the peak of the current Ipmp, the inverter INV2 outputs the signal FLGP1 at the “H” level that is generated based on the signal RES.

When the signal PCK_EN is at the “H” level, the operational amplifier AMP2 operates. In addition, the transistors T23 and T25 are brought to the on-state. When the voltage Vpref is applied to the gate of the transistor T21, the transistor T21 is brought to the on-state. This brings the transistors T22 and T24 to the on-state, and thus the currents Ipmrr and Ipmrr′ flow. As a result, the voltage VN25 at the node N25 is at a voltage level based on the magnitude relation between the current Ipmrr′ and the current Iref. Accordingly, the peak current sensing circuit 52 supplies the signal FLGP1 at the same logic level as the voltage VN25 to the logical product circuit ANDP.

On the other hand, when the signal PCK_EN is at the “L” level, the operational amplifier AMP2 does not operate. In addition, the transistors T23 and T25 are brought to the off-state. This brings the transistors T22 and T24 to the off-state. As a result, the voltage VN25 at the node N25 is at the “H” level. Accordingly, the peak current sensing circuit 52 supplies the signal FLGP1 at the “H” level to the logical product circuit ANDP.

For example, in a specific operation in which a relatively high peak current occurs, the peak current sensing circuit 52 executes the sensing of the peak current so that circuits and the like in the system that operates a chip are not broken. That is, the signal PCK_EN is brought to the “H” level in the specific operation. The specific operation is, for example, a leak test on the word lines WL. When sensing the peak current, the peak current sensing circuit 52 stops the voltage boosting performed by the booster circuit 53. The peak current sensing circuit 52 does not execute the sensing of the peak current in operations other than the specific operation (operations in which relatively low peak currents occur). That is, the signal PCK_EN is brought to the “L” level in the operations other than the specific operation.

A timing for switching the level of the signal PCK_EN is determined by the semiconductor memory device 3, for example, the sequencer 13. In this case, the sequencer 13 determines the timing for the switching and switches the level of the signal PCK_EN. Note that the timing for switching the level of the signal PCK_EN may be determined by the memory controller 2. In this case, the memory controller 2 may determine the timing for the switching and issue a command CMD for controlling the signal PCK_EN to the semiconductor memory device 3, and the sequencer 13 receiving the command CMD may switch the level of the signal PCK_EN.

### 1.1.8 Configuration of Booster Circuit

With reference to FIG. 6, a configuration of the booster circuit 53 will be described. FIG. 6 is a circuit diagram illustrating an example of the configuration of the booster circuit 53.

In various operations, the booster circuit 53 is configured to output the voltage Vpout higher than the voltage Vpsup from its output terminal when receiving the voltage Vpsup.

The booster circuit 53 includes, for example, charge pumps CP1 to CP4, switches SW31 to SW39, and a control circuit CC.

The charge pump CP1 is connected to nodes N31 and N32. The charge pump CP2 is connected to nodes N33 and N34. The charge pump CP3 is connected to nodes N35 and N36. The charge pump CP4 is connected to nodes N37 and N38. Hereinafter, when the charge pumps CP1 to CP4 are not distinguished from one another, the charge pumps CP1 to CP4 are each simply referred to as a charge pump CP.

The switches SW31 to SW39 each include a first terminal and a second terminal. The first terminal of the switch SW31 is connected to the node N32. The second terminal of the switch SW31 is connected to the node N38. The first terminal of the switch SW32 is connected to the node N32. The second terminal of the switch SW32 is connected to the node N33. The first terminal of the switch SW33 is connected to the node N31. The second terminal of the switch SW33 is connected to the node N33. The first terminal of the switch SW34 is connected to the node N31. The second terminal of the switch SW34 is connected to the node N35. The first terminal of the switch SW35 is connected to the node N31. The second terminal of the switch SW35 is connected to the node N37. The first terminal of the switch SW36 is connected to the node N34. The second terminal of the switch SW36 is connected to the node N38. The first terminal of the switch SW37 is connected to the node N34. The second terminal of the switch SW37 is connected to the node N35. The first terminal of the switch SW38 is connected to the node N36. The second terminal of the switch SW38 is connected to the node N38. The first terminal of the switch SW39 is connected to the node N36. The second terminal of the switch SW39 is connected to the node N37.

For example, the connections of the switches SW31 to SW39 are controlled by the sequencer 13. The sequencer 13 controls the connection of the switches SW31 to SW39 in accordance with a boosted voltage.

For example, in an erase operation, when the voltage Vpsup is boosted to a voltage VERA (e.g., 20 V) to be applied to a source line SL, the sequencer 13 turns on the switches SW32, SW37, and SW39 and turns off the switches SW31, SW33 to SW36, and SW38. This connects the charge pumps CP1 to CP4 together in series. For example, when the voltage Vpsup is boosted to about 3 or 4 V, the sequencer 13 turns on the switches SW31, SW33 to SW36, and SW38 and turns off the switches SW32, SW37, and SW39. This connects the charge pumps CP1 to CP4 together in parallel. Such control will be referred to as “second control.” The connections between the charge pumps are controlled in this manner so that the charge pumps are used efficiently (so as to output a voltage Vout effectively using the current Ipmp in a smaller amount).

Controlling the connections between the charge pumps is effective in curbing the peak current as with the ramp rate control but cannot necessarily guarantee the absolute value of the upper limit of the peak current.

### 1.1.9 Configuration of Charge Pump

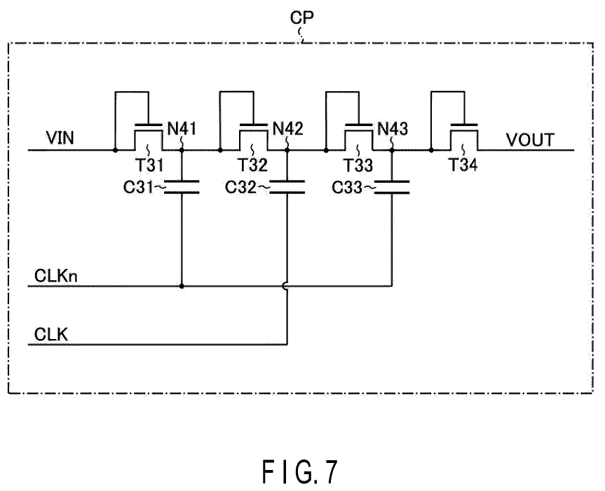

With reference to FIG. 7, a configuration of the charge pump CP will be described. FIG. 7 is a circuit diagram illustrating an example of the configuration of the charge pump CP.

The charge pump CP includes, for example, n-channel MOS transistors T31 to T34 and capacitive elements C31 to C33.

To a first terminal and a gate of the transistor T31, a voltage VIN is applied. The voltage VIN is a voltage input to the charge pump CP. A second terminal of the transistor T31 is connected to a node N41.

A first terminal and a gate of the transistor T32 are connected to the node N41. A second terminal of the transistor T32 is connected to a node N42.

A first terminal and a gate of the transistor T33 are connected to the node N42. A second terminal of the transistor T33 is connected to a node N43.

A first terminal and a gate of the transistor T34 are connected to the node N43. From a second terminal of the transistor T34, the voltage VOUT is output. The voltage VOUT is a voltage output from the charge pump CP.

To the charge pump CP, a signal CLK and a signal CLKn, which is an inverse signal of the signal CLK, are input. The signals CLK and CLKn are generated by, for example a driver or the like not illustrated that is included in the charge pump CP.

A first electrode of the capacitive element C31 is connected to the node N41. To a second electrode of the capacitive element C31, the signal CLKn is input. A first electrode of the capacitive element C32 is connected to the node N42. To a second electrode of the capacitive element C32, the signal CLK is input. A first electrode of the capacitive element C33 is connected to the node N43. To a second electrode of the capacitive element C33, the signal CLKn is input. Hereinafter, when the capacitive elements C31 to C33 are not distinguished from one another, the capacitive elements C31 to C33 are each simply referred to as a capacitive element C.

When the signal CLK turns to the “H” level, and the signal CLKn, which is the inverse signal of the signal CLK, turns to the “L” level, the transistor T31 and the transistor T33 are turned on, and the transistor T32 and the transistor T34 are turned off. This connects the first terminal of the transistor T31 and the node N41 and cuts connection between the node N41 and the node N42. In addition, this connects the node N42 and the node N43 and cuts connection between the node N43 and the second terminal of the transistor T34.

That is, when the signal CLK turns to the “H” level, and the signal CLKn, which is the inverse signal of the signal CLK, turns to the “L” level, a voltage (approximately the voltage VIN) that is the voltage VIN having been affected by a threshold voltage Vth to drop is transferred to the node N41. To the node N43, a voltage (approximately (VC2+VD)) that is a voltage at the node N42 (VC2+VD as described later) having been affected by the threshold voltage Vth to drop is transferred. VC2 is a voltage across the capacitive element C32 being charged. VD is a difference between a voltage at an “H” level and the voltage at an “L” level of the signal CLK (or the signal CLKn).

While the signal CLKn is at the “L” level, the capacitive element C31 is charged by the voltage VIN. This brings a voltage across the capacitive element C31 to VC1. While the signal CLKn is at the “L” level, the capacitive element C33 is charged by the voltage (VC2+VD) at the node N42. This brings a voltage across the capacitive element C33 to VC3.

When the signal CLK turns to the “H” level, the voltage at the node N42 is brought to a voltage (VC1+VD) that is the voltage VC1 across the capacitive element C31 boosted by the difference VD between the “H” level and the “L” level of the signal CLKn. The voltage VC1 is the voltage (approximately the voltage VIN) that is the voltage VIN having been affected by the threshold voltage Vth to drop. When the difference VD is assumed to be equal to the voltage VIN, the voltage at the node N42 is brought to approximately 2×VIN.

While the signal CLK is at the “H” level, the voltage at the node N42 is maintained at approximately 2×VIN.

When the signal CLK then turns to the “L” level, and the signal CLKn, which is the inverse signal of the signal CLK, turns to the “H” level, the transistor T31 and the transistor T33 are turned off, and the transistor T32 and the transistor T34 are turned on. This cuts the connection between the first terminal of the transistor T31 and the node N41 and connects the node N41 and the node N42. In addition, this cuts the connection between the node N42 and the node N43 and connects the node N43 and the second terminal of the transistor T34.

That is, when the signal CLK turns to the “L” level, and the signal CLKn, which is the inverse signal of the signal CLK, turns to the “H” level, a voltage at the node N41 is brought to the voltage (VC1+VD) that is the voltage VC1 across the capacitive element C31 boosted by the difference VD between the “H” level and the “L” level of the signal CLKn. The voltage at the node N41 is brought to approximately 2×VIN.

When the signal CLKn turns to the “H” level, a voltage at the node N43 is brought to a voltage (VC3+VD) that is a voltage VC3 across the capacitive element C33 boosted by the difference VD between the “H” level and the “L” level of the signal CLKn. The voltage at the node N43 is brought to approximately 3×VIN.

While the signal CLKn is at the “H” level, the voltage at the node N43 is maintained at approximately 3×VIN.

When the signal CLKn turns to the “H” level, the voltage at the node N43 (approximately 3×VIN) is transferred as the voltage VOUT.

When the signal CLK turns to the “L” level, the voltage at the node N41 (approximately 2×VIN) is transferred to the node N42.

While the signal CLK is at the “L” level, the capacitive element C32 is charged by a voltage of approximately 2×VIN. This brings the voltage across the capacitive element C32 to VC2.

As seen from the above, when the signal CLK turns to the “H” level, the voltage VIN is transferred to the node N41, and the voltage at the node N42 (approximately 2×VIN) is transferred to the node N43. The voltage at the node N42 is boosted by VD (VIN) to be brought to approximately 2×VIN. When the signal CLK then turns to the “L” level, the voltage at the node N41 is boosted by VD (VIN) to be brought to approximately 2×VIN. The voltage at the node N43 is boosted by VD (VIN) to be brought to approximately 3×VIN. To the node N42, the voltage at the node N41 (approximately 2×VIN) is transferred. Then, as the voltage VOUT, the voltage at the node N43 (approximately 3×VIN) is output.

In the example illustrated in FIG. 7, the charge pump CP includes the three capacitive elements C31 to C33. However, the number of the capacitive elements C included in the charge pump CP is not limited to three. The number of the capacitive elements C may be two, four, or five or more and can be changed in accordance with, for example, a target value of a voltage to be boosted to. In this case, to a second electrode of a capacitive element C (2j-1) (j is a natural number), for example, the signal CLKn is input. To a second electrode of a capacitive element C (2j), for example, the signal CLK is input. Note that the number of the transistors is changed as appropriate in accordance with the number of the capacitive elements C.

Note that the configuration of the charge pumps CP1 to CP4 is not limited to the example described with reference to FIG. 7. The charge pump CP may include, for example, p-channel MOS transistors. The charge pump CP may be, for example, a charge pump with Vt cancellation, which is constituted by transistors in each of which its first terminal and its gate are not made equipotential, rather than diode-connected transistors.

### 1.2 Advantageous Effect According to Present Embodiment

According to the present embodiment, it is possible to curb a peak current that occurs in a booster circuit (the peak current that flows in the booster circuit). This advantageous effect will be described below.

In a semiconductor memory device, for example, when the voltage VERA is applied to a source line SL in an erase operation, or when the voltage VREAD is applied to non-selected word lines WL in a read operation, a relatively high peak current may occur in a booster circuit.

A substrate and a system on which the semiconductor memory device is mounted are designed in such a manner as to withstand the peak current. For example, the substrate and the system are designed to prevent the substrate or the system from being damaged by an excessive rise in temperature caused by the peak current. In addition, the substrate and the system are designed to supply a voltage that can withstand the peak current. Designing with consideration given to the temperature and an amount of the voltage supply in this manner may influence costs and reliability.

For this reason, the semiconductor memory device is equipped with measures to perform the first control and the second control described above so as to curb the peak current that occurs in the booster circuit.

However, for example, if a load connected to the booster circuit rapidly fluctuates, only the first control and the second control described above may be insufficient to curb the peak current that occurs in the booster circuit. The rapid fluctuation of the load occurs when, for example, a selection gate line SGD is brought to an on-state in various operations.

For this reason, for example, it is possible in the first control to additionally control a rate of increase of a voltage output from the booster circuit in accordance with the fluctuation of the load. However, in this case, the first control may be complicated.

In contrast to this, the voltage generation circuit 14 included in the semiconductor memory device according to the present embodiment includes the transistor T1, the peak current sensing circuit 52, and the booster circuit 53. To the gate of the transistor T1, the reference voltage Vpref is applied. To the first terminal of the transistor T1, the power voltage VCC is applied. The second terminal of the transistor T1 is connected to the node N2. The peak current sensing circuit 52 is connected to the node N2 and senses the peak of the current Ipmp flowing from the transistor T1 to the booster circuit 53. The booster circuit 53 is connected to the node N2, boosts the voltage Vpsup at the node N2, and outputs the voltage Vpout that is the boosted voltage of Vpsup. The booster circuit 53 stops the voltage boosting based on the sensing result FLGP1 from the peak current sensing circuit 52. In other words, when sensing the peak of the current Ipmp, the peak current sensing circuit 52 stops the voltage boosting performed by the booster circuit 53. This can curb the peak current that occurs in the booster circuit 53.

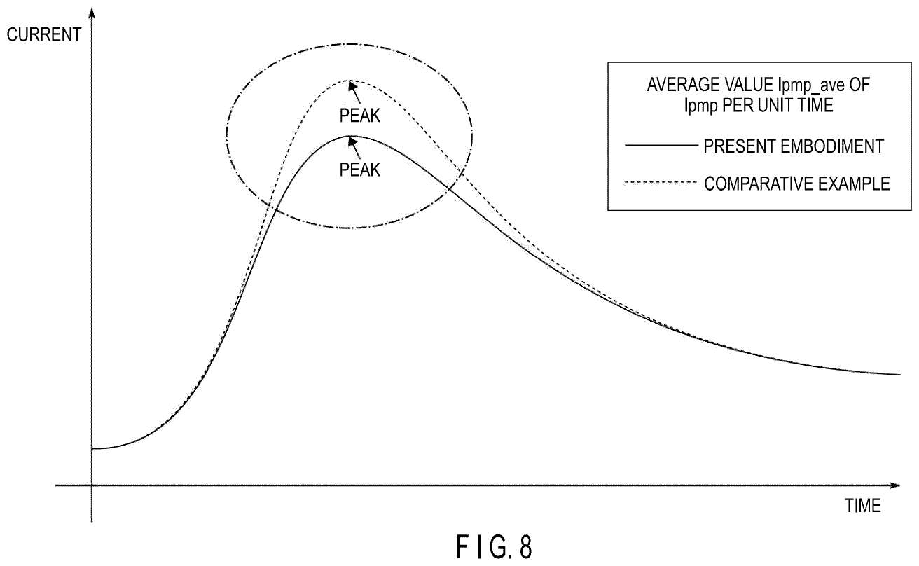

FIG. 8 is a graph illustrating an example of a waveform of a current flowing through the booster circuit 53 in the voltage generation circuit 14 according to the present embodiment and an example of a waveform of a current flowing through a booster circuit 53 in a voltage generation circuit 14 according to a comparative example. A vertical axis indicates current. A horizontal axis indicates time. Note that FIG. 8 illustrates a waveform of a current Ipmp_ave, which is the current Ipmp flowing through the booster circuit 53 expressed in terms of average value per unit time. The waveform of the current Ipmp_ave of the voltage generation circuit 14 according to the present embodiment is drawn with a solid line. The waveform of the current Ipmp_ave of the voltage generation circuit 14 according to the comparative example is drawn with a broken line.

The voltage generation circuit 14 according to the comparative example is the voltage generation circuit 14 illustrated in FIG. 5 from which the peak current sensing circuit 52 and the logical product circuit ANDP are omitted. In addition, to the booster circuit 53 in the voltage generation circuit 14 according to the comparative example, the signal FLGP2 is input via the node N5.

In voltage generation circuit 14 according to the present embodiment, the peak current sensing circuit 52 senses the peak of the current Ipmp. When sensing the peak of the current Ipmp, the peak current sensing circuit 52 stops the voltage boosting performed by the booster circuit 53.

For this reason, the current Ipmp in the booster circuit 53 in the voltage generation circuit 14 according to the present embodiment is curbed to a current that is lower than a current Ipmp in the booster circuit 53 in the voltage generation circuit 14 according to the comparative example, which is not provided with the peak current sensing circuit 52. In addition, the current Ipmrr (Ipmrr′) in the peak current sensing circuit 52 in the voltage generation circuit 14 according to the present embodiment is curbed to a current that is lower than the reference current Iref. Accordingly, as illustrated in FIG. 8, in a region enclosed by a chain line, the peak of the current Ipmp_ave in the booster circuit 53 in the voltage generation circuit 14 according to the present embodiment is curbed to a value that is lower than the peak of the current Ipmp_ave in the booster circuit 53 in the voltage generation circuit 14 according to the comparative example. As seen from the above, according to the present embodiment, it is possible to curb peak current flowing through the booster circuit 53.

### 1.3 First Modification

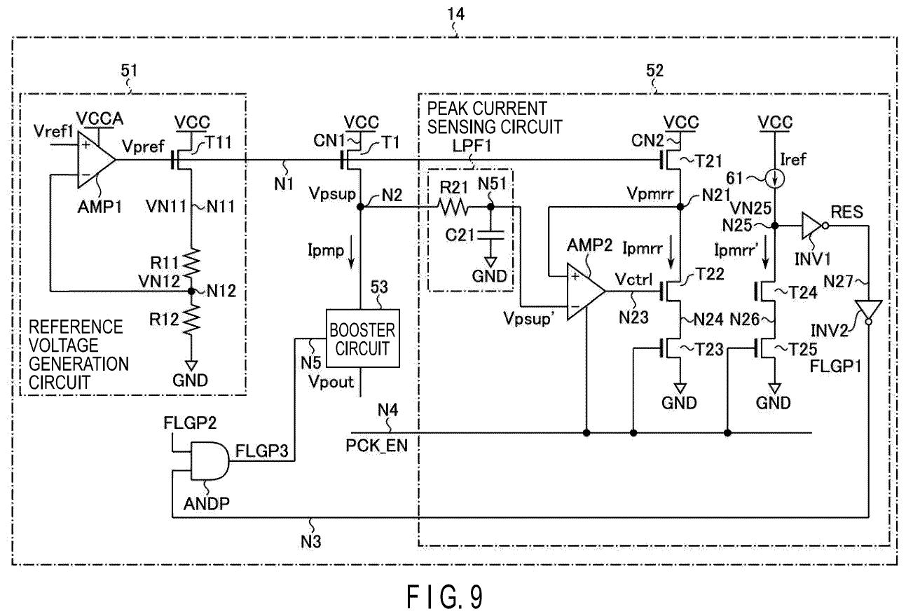

A memory system that includes a semiconductor memory device according to a first modification of the first embodiment will be described. The semiconductor memory device according to the first modification of the first embodiment differs from the first embodiment illustrated in FIG. 5 in the configuration of the peak current sensing circuit 52 in the voltage generation circuit 14. FIG. 9 is a circuit diagram illustrating an example of a configuration of the voltage generation circuit 14. The following description will be given mainly of differences from the first embodiment.

### 1.3.1 Configuration of Peak Current Sensing Circuit

As illustrated in FIG. 9, the one end of the low-pass filter LPF1 is connected to the node N2. The other end of the low-pass filter LPF1 is connected to a first input terminal of an operational amplifier AMP2. The low-pass filter LPF1 supplies the voltage Vpsup′, which is the voltage Vpsup at the node N2 with noise removed, to the first input terminal of the operational amplifier AMP2 via a node N51.

The one end of the resistive element R21 is connected to the node N2. The other end of the resistive element R21 is connected to the node N51. The first electrode of the capacitive element C21 is connected to the node N51. The second electrode of the capacitive element C21 is grounded.

The output terminal of the operational amplifier AMP2 is connected to the node N23. The operational amplifier AMP2 outputs the generated voltage Vctrl from the output terminal via the node N23 to the gate of the transistor T22.

### 1.3.2 Advantageous Effect According to Present Modification

The present modification provides an advantageous effect similar to that of the first embodiment.

### 1.4 Second Modification

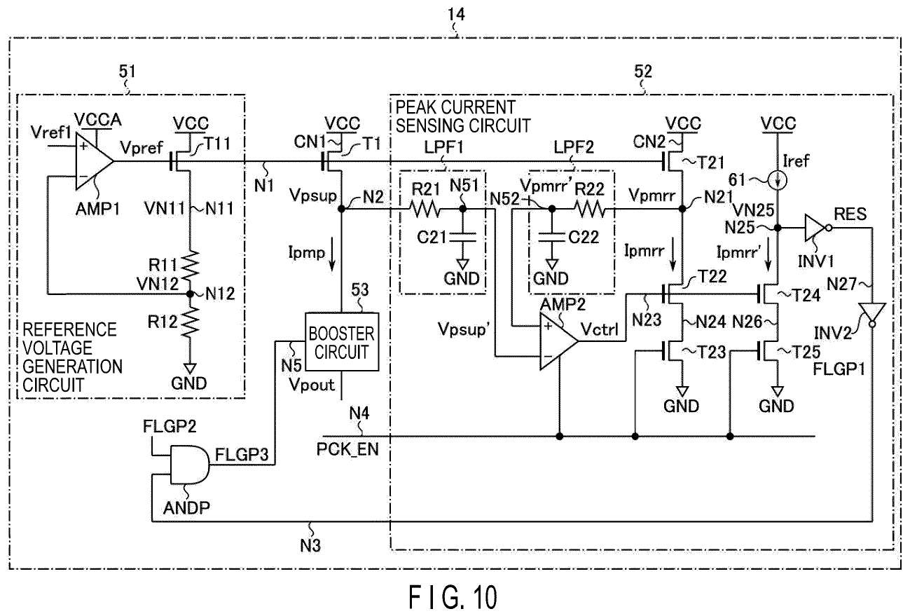

A memory system that includes a semiconductor memory device according to a second modification of the first embodiment will be described. The semiconductor memory device according to the second modification of the first embodiment differs from the first modification of the first embodiment illustrated in FIG. 9 in the configuration of the peak current sensing circuit 52 in the voltage generation circuit 14. FIG. 10 is a circuit diagram illustrating an example of a configuration of the voltage generation circuit 14. The following description will be given mainly of differences from the first modification of the first embodiment.

### 1.4.1 Configuration of Peak Current Sensing Circuit

As illustrated in FIG. 10, the peak current sensing circuit 52 further includes a low-pass filter LPF2.

One end of the low-pass filter LPF2 is connected to the node N21. The other end of the low-pass filter LPF2 is connected to the second input terminal of the operational amplifier AMP2. The low-pass filter LPF2 supplies the voltage Vpmrr′, which is the voltage Vpmrr at the node N21 with noise removed, to the second input terminal of the operational amplifier AMP2 via a node N52. The low-pass filter LPF2 includes a resistive element R22 and a capacitive element C22.

One end of the resistive element R22 is connected to the node N21. The other end of the resistive element R22 is connected to the node N52. A first electrode of the capacitive element C22 is connected to the node N52. A second electrode of the capacitive element C22 is grounded.

### 1.4.2 Advantageous Effect According to Present Modification

The present modification provides an advantageous effect similar to that of the first embodiment.

### 2. Second Embodiment

A memory system that includes a semiconductor memory device according to a second embodiment will be described.

### 2.1 Relation Between Voltage VCC, and Voltage Vpref and Voltage Vpsup

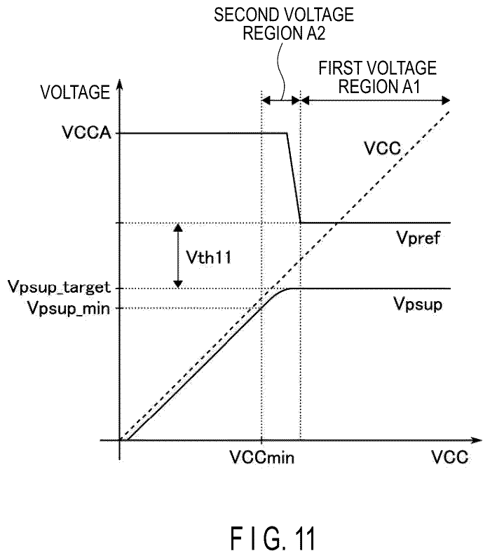

Before description of the semiconductor memory device according to the second embodiment, a relationship between the power voltage VCC, and the reference voltage Vpref and the voltage Vpsup that is supplied to the booster circuit 53 in the semiconductor memory device according to the first embodiment will be first described with reference to FIG. 11 and FIG. 5 that is illustrated for the first embodiment. FIG. 11 is a graph illustrating the relationship between the power voltage VCC, and the reference voltage Vpref and the voltage Vpsup in the semiconductor memory device according to the first embodiment. A vertical axis indicates the reference voltage Vpref and the voltage Vpsup. A horizontal axis indicates the power voltage VCC.

The voltage VCC can take on, for example, a value ranging from 2.3 V to 3.6 V. A voltage VCCmin is a lower limit value of the voltage VCC. In a case where the voltage VCC takes on the value ranging from 2.3 V to 3.6 V, the voltage VCCmin is 2.3 V.

A voltage Vpsup_min is a value of the voltage Vpsup at the voltage VCCmin.

A voltage Vpsup_target is a target value of the voltage Vpsup that is set in advance. The voltage Vpsup_target is set to a value up to which no overvoltage violation occurs in the booster circuit 53. This is for, as described above, preventing a voltage boosted by the booster circuit 53 from becoming excessively high to break the booster circuit 53 itself or another circuit and the like. In addition, the voltage Vpsup_target is set to a value that is relatively close to the voltage VCCmin. This is because increasing the voltage Vpsup_target as much as possible can improve an efficiency of the current Ipmp flowing through the booster circuit 53, thus reducing power consumption.

Hereinafter, a region where the voltage VCC is equal to or higher than the voltage Vpsup_target will be referred to as a “first voltage region A1.” A region where the voltage VCC is equal to or higher than the voltage VCCmin and lower than the voltage Vpsup_target will be referred to as a “second voltage region A2.”

When a value of the voltage VCC is within the first voltage region A1 (a value of the voltage VCC is sufficiently higher than the voltage VCCmin), the reference voltage Vpref is brought by the source follower to a voltage (a constant value) higher than the voltage VN11 at the node N11 by the threshold voltage Vth11 of the transistor T11 as described above. The voltage Vpsup is controlled to be at the same voltage level as the voltage VN11, to be the voltage Vpsup_target that is set in advance.

That is, when the value of the voltage VCC is within the first voltage region A1, the voltage Vpsup is regulated by the source follower. The voltage Vpmrr at the node N21 is also regulated by the source follower. For this reason, the voltage Vpsup is not affected by a resistance of the first terminal side of the transistor T1 (a parasitic resistance of the wire CN1 and an on-resistance of the transistor T1). The voltage Vpmrr is also not affected by a resistance of the first terminal side of the transistor T21 (a parasitic resistance of the wire CN2 and an on-resistance of the transistor T21). Accordingly, when the value of the voltage VCC is within the first voltage region A1, the peak current sensing circuit 52 can sense the peak current irrespective of the parasitic resistances of the wires CN1 and CN2 and the on-resistance of the transistors T1 and T21.

In contrast, when the value of the voltage VCC is within the second voltage region A2 (the value of the voltage VCC is relatively close to the voltage VCCmin), the voltage VN11 at the node N11 drops. When the voltage VN11 drops, the reference voltage Vpref rises as a result of feedback, to be the voltage VCCA, a maximum voltage that the amplifier AMP1 can supply (e.g., 3.8 V). This causes the voltage Vpsup to decrease below the voltage Vpsup_target.

That is, when the value of the voltage VCC is within the second voltage region A2, the voltage Vpsup is not regulated, and the voltage Vpsup takes on a value based on the resistance of the first terminal side of the transistor T1 (the parasitic resistance of the wire CN1 and the on-resistance of the transistor T1). The voltage Vpmrr is also not regulated, and the voltage Vpmrr takes on a value based on the resistance of the first terminal side of the transistor T21 (the parasitic resistance of the wire CN2 and the on-resistance of the transistor T21). This is because the transistors T1 and T21 simply operate as switches. When the reference voltage Vpref is relatively high (e.g., the voltage VCCA), the on-resistances of the transistors T1 and T21 approach zero. However, the parasitic resistances of the wires CN1 and CN2 are not negligible. For this reason, when the value of the voltage VCC is within the second voltage region A2, the current Ipmrr (Ipmrr′) is not brought to Ipmp×(w/W)) by an influence of the parasitic resistances of the wires CN1 and CN2, and thus it may be difficult for the peak current sensing circuit 52 to sense the peak current.

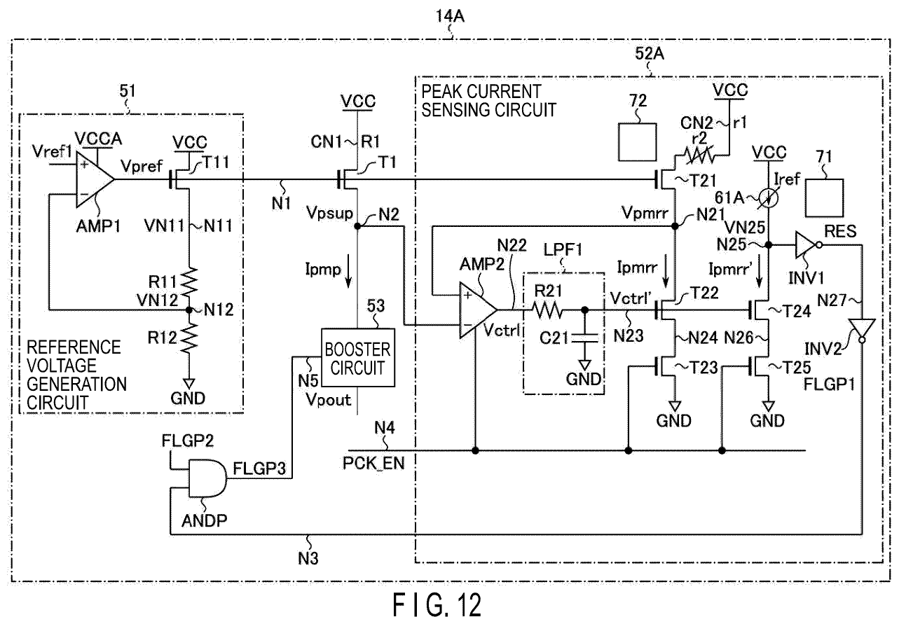

The semiconductor memory device according to the second embodiment has a configuration that can sense the peak current not only when the value of the voltage VCC is within the first voltage region A1 but also when the value of the voltage VCC is within the second voltage region A2. The semiconductor memory device according to the second embodiment differs from the first embodiment illustrated in FIG. 5 in the configuration of the voltage generation circuit 14. Hereinafter, a voltage generation circuit 14 in the semiconductor memory device according to the second embodiment will be referred to as a “voltage generation circuit 14A.” A peak current sensing circuit 52 in the voltage generation circuit 14A will be referred to as a “peak current sensing circuit 52A.” A current source 61 in the peak current sensing circuit 52A will be referred to as a “current source 61A.” FIG. 12 is a circuit diagram illustrating an example of a configuration of the voltage generation circuit 14A. The following description will be given mainly of differences from the first embodiment.

### 2.2 Configuration of Voltage Generation Circuit

The voltage generation circuit 14A includes, as with the first embodiment, a wire CN1 for supplying a voltage VCC to a transistor T1. Hereinafter, a parasitic resistance of the wire CN1 will be denoted as R1.

To one end of the wire CN1, the voltage VCC is supplied. The other end of the wire CN1 is connected to a first terminal of the transistor T1.

The wire CN1 from a power source pad for the power voltage VCC to the first terminal of the transistor T1 can be formed as a relatively short wire. For this reason, the parasitic resistance R1 can be made relatively low.

### 2.3 Configuration of Peak Current Sensing Circuit

The peak current sensing circuit 52A includes, as with the first embodiment, a wire CN2 for supplying the voltage VCC to a transistor T21. Hereinafter, a parasitic resistance of the wire CN2 will be denoted as r1.

The current source 61A is a variable current source.

In addition to the configuration in FIG. 5 described in the first embodiment, the peak current sensing circuit 52A further includes a resistive element r2, and calibration circuits 71 and 72.

The resistive element r2 is a variable resistive element.

To one end of the wire CN2, the voltage VCC is supplied. The other end of the wire CN2 is connected to one end of the resistive element r2. The other end of the resistive element r2 is connected to a first terminal of the transistor T21.

The wire CN2 from a power source pad for the power voltage VCC to the first terminal of the transistor T21 may be long compared with the wire CN1. For this reason, the resistive element r2 is provided so that a resistance of the first terminal side of the transistor T21 can be adjusted.

The calibration circuit 71 is a circuit that calibrates a current value of the current source 61A in a state where the voltage VCC is set to have a voltage value equal to or higher than the voltage Vpsup_target (a value within the first voltage region A1 illustrated in FIG. 11). As described above, when the value of the voltage VCC is within the first voltage region A1, the voltage Vpsup is not affected by the resistance of a first terminal side of the transistor T1. The voltage Vpmrr is not affected by the resistance of the first terminal side of the transistor T21. For this reason, for example, the calibration circuit 71 calibrates the current value of the current source 61A to a current Ipmp×(a size of the transistor T21 (a gate width w)/a size of the transistor T1 (a gate width W)) in a state where the voltage VCC is set to be a value within the first voltage region A1.

The calibration circuit 72 is a circuit that calibrates a resistance value of the resistive element r2 in a state where the voltage VCC is set to have a voltage value lower than the voltage Vpsup_target (a value within the second voltage region A2 illustrated in FIG. 11). As described above, when the value of the voltage VCC is within the second voltage region A2, the voltage Vpsup is brought to a voltage based on the resistance of a first terminal side of the transistor T1. The voltage Vpmrr is brought to a voltage based on the resistance of the first terminal side of the transistor T21. For this reason, for example, the calibration circuit 72 calibrates the resistance value of the resistive element r2 in a state where the value of the voltage VCC is set to be within the second voltage region A2, such that a ratio between the parasitic resistance R1 of the wire CN1 and a combined resistance of the parasitic resistance r1 of the wire CN2 and the resistive element r2 is the inverse of a ratio between the size W of the transistor T1 and the size w of the transistor T21.

When a logic level of a signal FLGP1 is inverted, a current Ipmrr (a current Ipmrr′) is equal to a current Iref. That is, the resistance value of the resistive element r2 when the logic level of the signal FLGP1 is inverted is a resistance value that makes the current Ipmrr (the current Ipmrr′) equal to the current Iref when the value of the voltage VCC is within the second voltage region A2. For this reason, when the logic level of the signal FLGP1 is inverted, the calibration circuit 72 can determine that the ratio between the parasitic resistance R1 and the combined resistance of the parasitic resistance r1 and the resistive element r2 is the inverse of the ratio between the size W of the transistor T1 and the size w of the transistor T21. Accordingly, in the state where the value of the voltage VCC is set to be within the second voltage region A2, the calibration circuit 72 monitors the signal FLGP1 and calibrates the resistance value of the resistive element r2 to the resistance value of the resistive element r2 of a time when the logic level of the signal FLGP1 is inverted.

### 2.4 Operations of Voltage Generation Circuit

Operations of the voltage generation circuit 14A according to the present embodiment further include a calibration operation and a setting operation, in addition to the peak current sensing operation described in the first embodiment.

The calibration operation is an operation of calibrating the current value of the current source 61A and the resistance value of the resistive element r2. For example, the calibration operation is performed in a test after production and before shipment. The setting operation is an operation of setting the current value of the current source 61A and the resistance value of the resistive element r2 to values calibrated by the calibration operation. For example, the setting operation is performed at power-on after shipment.

### Calibration Operation

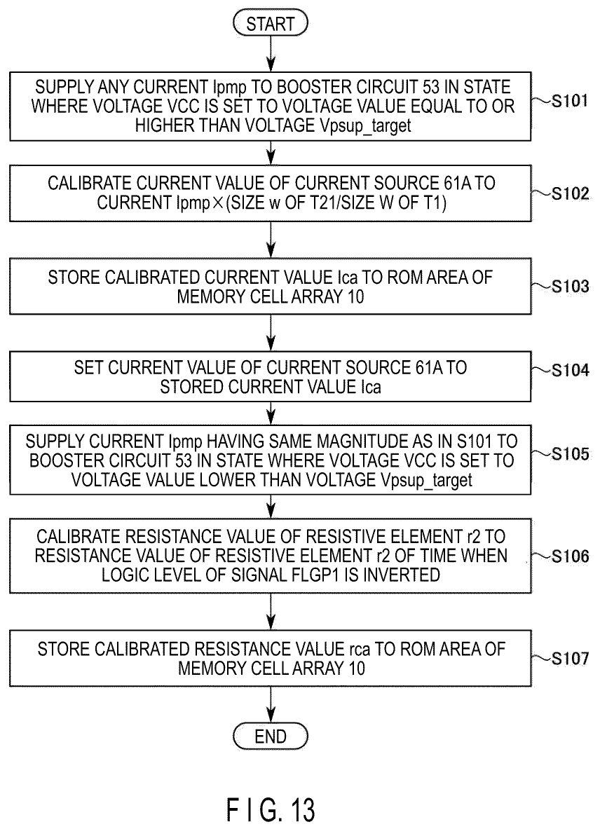

With reference to FIG. 13, the calibration operation will be described. FIG. 13 is a flowchart illustrating an example of the calibration operation of the voltage generation circuit 14A.

When the test before shipment is started, the voltage generation circuit 14A supplies any current Ipmp (e.g., 10 mA) to the booster circuit 53 in a state where the voltage VCC is set to a voltage value equal to or higher than the voltage Vpsup_target (a value within the first voltage region A1 illustrated in FIG. 11) (S101).

Next, the calibration circuit 71 changes the current value of the current source 61A. The calibration circuit 71 then calibrates the current value of the current source 61A to the current Ipmp×(the size w of the transistor T21/the size W of the transistor T1) (S102). Hereinafter, the calibrated current value of the current source 61A (a digital value) will be referred to as “Ica.”

Next, the calibration circuit 71 stores the current value Ica of the current source 61A obtained in step S102 in a ROM area of the memory cell array 10 (S103).

Next, the voltage generation circuit 14A sets the current value of the current source 61A to the current value Ica stored in step S103 (S104). This causes the current source 61A to supply the current Ica as the current Iref.

Next, the voltage generation circuit 14A supplies the current Ipmp having the same magnitude as in step S101 to the booster circuit 53 in a state where the voltage VCC is set to a voltage value lower than the voltage Vpsup_target (a value within the second voltage region A2 illustrated in FIG. 11) (S105).

Next, the calibration circuit 72 monitors the signal FLGP1 while changing the resistance value of the resistive element r2. The calibration circuit 72 then calibrates the resistance value of the resistive element r2 to the resistance value of the resistive element r2 of the time when the logic level of the signal FLGP1 is inverted (S106). Hereinafter, the calibrated resistance value of the resistive element r2 (a digital value) will be referred to as “rca.”

Next, the calibration circuit 72 stores the resistance value rca of the resistive element r2 obtained in step S106 in the ROM area of the memory cell array 10 (S107).

Note that the steps S101 to S103 may be omitted. In this case, steps S104 to S107 can be performed with the current value Ica of the current source 61A being stored in advance in the ROM area of the memory cell array 10.

### Setting Operation

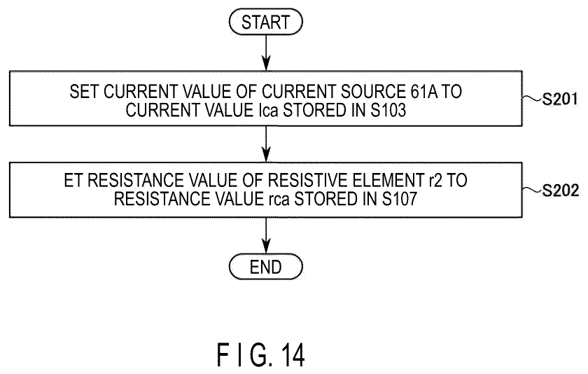

With reference to FIG. 14, the setting operation will be described. FIG. 14 is a flowchart illustrating an example of the setting operation of the voltage generation circuit 14A.

When the semiconductor memory device 3 is powered on, the voltage generation circuit 14A sets the current value of the current source 61A to the current value Ica stored in step S103 (S201). Next, the voltage generation circuit 14A sets the resistance value of the resistive element r2 to the resistance value rca stored in step S107 (S202). This causes the ratio between the parasitic resistance R1 and the combined resistance of the parasitic resistance r1 and the resistive element r2 to be in inverse ratio of the ratio between the size W of the transistor T1 and the size w of the transistor T21.

### 2.5 Advantageous Effect According to Present Embodiment

In the semiconductor memory device according to the present embodiment, the peak current sensing circuit 52A further includes, in addition to the configuration in FIG. 5 described in the first embodiment, the resistive element r2 being a variable resistive element and the calibration circuits 71 and 72. In addition, as the current source 61A of the peak current sensing circuit 52A, a variable current source is used.

With the configuration described above, for example, the calibration circuit 71 calibrates the current value of the current source 61A to the current Ipmp×(the size w of the transistor T21/the size W of the transistor T1) in the state where the voltage VCC is set to be a value within the first voltage region A1 in the test before shipment. After the current value of the current source 61A is calibrated, the calibration circuit 72 calibrates the resistance value of the resistive element r2 in the state where the value of the voltage VCC is set to be within the second voltage region A2, such that the ratio between the parasitic resistance R1 and the combined resistance of the parasitic resistance r1 and the resistive element r2 is in inverse ratio of the ratio between the size W of the transistor T1 and the size w of the transistor T21.

Then, for example, at power-on after shipment, the voltage generation circuit 14A sets the current value of the current source 61A to the calibrated current value Ica. The resistance value of the resistive element r2 is set to the calibrated resistance value rca. This causes the ratio between the parasitic resistance R1 and the combined resistance of the parasitic resistance r1 and the resistive element r2 to be in inverse ratio of the ratio between the size W of the transistor T1 and the size w of the transistor T21.

Accordingly, the peak current sensing circuit 52A can bring the current Ipmrr (Ipmrr′) to Ipmp×(w/W)) not only when the value of the voltage VCC is within the first voltage region A1 but also when the value of the voltage VCC is within the second voltage region A2, and thus can sense the peak current in the peak current sensing operation. Therefore, according to the present embodiment, it is possible to curb the peak current that occurs in the booster circuit 53 not only when the value of the voltage VCC is within the first voltage region A1 but also when the value of the voltage VCC is within the second voltage region A2.

Naturally, the first modification and the second modification of the first embodiment can be applied to the semiconductor memory device 3 according to the present embodiment.

### 3. Modifications, Etc

As described above, the voltage generation circuit (14/14A) according to the embodiments includes a first transistor (T1), a first circuit (53), and a second circuit (52/52A). To a gate of the first transistor (T1), the reference voltage (Vpref) is applied. To a first terminal of the first transistor (T1), the power voltage (VCC) is applied. A second terminal of the first transistor (T1) is connected to a first node (N2). The first circuit (53) is connected to a first node (N2), boosts a first voltage (Vpsup) at the first node, and outputs a second voltage (Vpout) that is the boosted first voltage (Vpsup). The second circuit (52/52A) is connected to the first node (N2) and senses the peak of a first current (Ipmp) flowing from the first transistor (T1) to the first circuit (53). The first circuit (53) stops the voltage boosting based on the sensing result (FLGP1) from the second circuit (52/52A).

Note that the embodiments are not limited to the embodiments described above and can be subjected to various modifications.

In addition, in each of the flowcharts described in the above embodiment, its order can be changed to a maximum extent.

While certain embodiments have been described, these embodiments have been presented by way of example only, and are not intended to limit the scope of the inventions. Indeed, the novel devices and methods described herein may be embodied in a variety of other forms; furthermore, various omissions, substitutions, and changes in the form of the embodiments described herein may be made without departing from the spirit of the inventions. The accompanying claims and their equivalents are intended to cover such forms or modification as would fall within the scope and spirit of the inventions.

What is claimed is:

1. A voltage generation circuit comprising:
a first transistor including a gate to which a reference voltage is applied, a first terminal to which a power voltage is applied, and a second terminal that is connected to a first node;
a first circuit connected to the first node, and configured to boost a first voltage at the first node and output the boosted first voltage as a second voltage; and
a second circuit connected to the first node, and configured to sense a first current that flows from the first transistor to the first circuit, wherein
the first circuit is configured to stop the boosting of the first voltage based on a sensing result from the second circuit.

2. The voltage generation circuit of claim 1, wherein the sensing result indicates whether or not the first current is greater than a reference current.

3. The voltage generation circuit of claim 2, wherein the second circuit is configured to generate the sensing result based on a second current that is proportional to the first current.

4. The voltage generation circuit of claim 3, wherein the second circuit is configured to generate the sensing result by comparing the second current with a reference current.

5. The voltage generation circuit of claim 4, wherein
the second circuit is configured to output a first sensing result when the second current is higher than the reference current, and a second sensing result when the second current is equal to or lower than the reference current, and
the first circuit stops the boosting of the first voltage in response to the first sensing result and does not stop the boosting of the first voltage in response to the second sensing result.

6. The voltage generation circuit of claim 1, wherein the second circuit is configured to stop sensing the first current in response to a control signal.

7. The voltage generation circuit of claim 1, wherein
the second circuit includes:
a second transistor including a gate to which the reference voltage is applied, a first terminal to which the power voltage is applied, and a second terminal that is connected to a second node;
an operational amplifier including a first input terminal to which the first voltage at the first node is applied, a second input terminal to which a third voltage at the second node is applied, and an output terminal from which the operational amplifier outputs a fourth voltage based on the first voltage and the third voltage;
a third transistor including a gate to which a fifth voltage based on the fourth voltage is applied, a first terminal that is connected to the second node, and a second terminal that is connected to a third node;
a current source that supplies a reference current to a fourth node;
a fourth transistor including a gate to which the fifth voltage is applied, a first terminal that is connected to the fourth node, and a second terminal that is connected to a fifth node; and
an inverter including an input terminal to which a sixth voltage at the fourth node is applied and an output terminal from which the inverter outputs a second signal based on the sixth voltage, wherein
the sensing result is a signal that is generated by the second circuit based on the second signal.

8. The voltage generation circuit of claim 7, wherein the second transistor is smaller in size than the first transistor.

9. The voltage generation circuit of claim 7, wherein
the second circuit further includes:
a fifth transistor including a gate to which a control signal is input, a first terminal that is connected to the third node, and a second terminal that is grounded; and
a sixth transistor including a gate to which the control signal is input, a first terminal that is connected to the fifth node, and a second terminal that is grounded, wherein
the operational amplifier further includes a control terminal to which the control signal is input, and
the operational amplifier operates based on the control signal.

10. The voltage generation circuit of claim 7, wherein
the second circuit further includes a filter, and
one end of the filter is connected to the output terminal of the operational amplifier, and another end of the filter is connected to the gate of the third transistor.

11. The voltage generation circuit of claim 7, wherein
the second circuit further includes a filter, and
one end of the filter is connected to the first node, and another end of the filter is connected to the first input terminal of the operational amplifier.

12. The voltage generation circuit of claim 7, wherein
the second circuit further includes:
a first filter; and
a second filter, wherein
one end of the first filter is connected to the first node, and another end of the first filter is connected to the first input terminal of the operational amplifier, and
one end of the second filter is connected to the second node, and another end of the second filter is connected to the second input terminal of the operational amplifier.

13. The voltage generation circuit of claim 7, further comprising
a first wire, wherein
one end of the first wire is supplied with the power voltage, and another end of the first wire is connected to the first terminal of the first transistor,
the second circuit further includes:
a second wire;
a variable resistive element; and
a first calibration circuit,
one end of the second wire is supplied with the power voltage, and another end of the second wire is connected to one end of the variable resistive element,
another end of the variable resistive element is connected to the first terminal of the second transistor,
the current source is a variable current source, and
the first calibration circuit is configured to calibrate a current value of the current source to a product of the first current and a ratio of a size of the second transistor to a size of the first transistor.

14. The voltage generation circuit of claim 13, wherein
the second circuit further includes a second calibration circuit, and
the second calibration circuit is configured to calibrate a resistance value of the variable resistive element such that a ratio of a parasitic resistance of the first wire to a combined resistance of a parasitic resistance of the second wire and the variable resistive element is the inverse of a ratio of the size of the first transistor to the size of the second transistor.

15. The voltage generation circuit of claim 13, wherein
the second circuit further includes a second calibration circuit, and
the second calibration circuit is configured to calibrate a resistance value of the variable resistive element to a resistance value of the variable resistive element at a time when a logic level of the sensing result is inverted.

16. The voltage generation circuit of claim 7, further comprising
a first wire, wherein
one end of the first wire is supplied with the power voltage, and another end of the first wire is connected to the first terminal of the first transistor,
the second circuit further includes:
a second wire; and
a variable resistive element,
one end of the second wire is supplied with the power voltage, and another end of the second wire is connected to one end of the variable resistive element,
another end of the variable resistive element is connected to the first terminal of the second transistor, and
a ratio of a parasitic resistance of the first wire to a combined resistance of a parasitic resistance of the second wire and the variable resistive element is the inverse of a ratio of a size of the first transistor to a size of the second transistor.

17. The voltage generation circuit of claim 1, wherein the first circuit is configured to stop the boosting of the first voltage based further on a fourth signal that is generated based on the second voltage.

18. The voltage generation circuit of claim 17, further comprising
a third circuit including a first terminal to which the sensing result is input, a second terminal to which the fourth signal is input, and a third terminal, wherein the third circuit is configured to calculate a logical product of the sensing result and the fourth signal and output the calculated logical product through the third terminal, wherein
the first circuit is configured to stop the boosting of the first voltage based on the calculated logical product.

19. A semiconductor memory device comprising:
memory cells; and
a voltage generation circuit including
a first transistor including a gate to which a reference voltage is applied, a first terminal to which a power voltage is applied, and a second terminal that is connected to a first node;
a first circuit connected to the first node, and configured to boost a first voltage at the first node and output the boosted first voltage as a second voltage that is supplied to the memory cells; and
a second circuit connected to the first node, and configured to sense a first current that flows from the first transistor to the first circuit, wherein the first circuit is configured to stop the boosting of the first voltage based on a sensing result from the second circuit.

20. The semiconductor memory device of claim 19, further comprising
a fourth circuit configured to control the voltage generating circuit, wherein
the fourth circuit generates a control signal for enabling the second circuit to sense the first current and transmits the control signal to the voltage generation circuit.
